(19) United States
(12) Patent Application Publication
(10) Pub. No.: US 2026/0323917 A1
(43) Pub. Date: Oct. 15, 2026

(54) MEMORY DEVICE AND METHOD FOR FORMING THE SAME

(71) Applicant: NANYA TECHNOLOGY CORPORATION, New Taipei City (TW)

(72) Inventor: Kai Hung LIN, New Taipei City (TW)

(21) Appl. No.: 19/176,184

(22) Filed: Apr. 11, 2025

(51) Int. Cl. H10B 12/00; H10D 1/00; H10D 1/68

(52) U.S. Cl. CPC H10B 12/318; H10B 12/033; H10D 1/042; H10D 1/696; H10D 1/714; H10D 1/716

(57) ABSTRACT

A method for forming a memory device includes forming a stack over a substrate. The stack includes a first supporting layer, a first sacrificial layer, a second supporting layer, a second sacrificial layer, and a third supporting layer. The method further includes forming a trench in the stack. The method further includes forming a bottom electrode in the trench. Forming the bottom electrode in the trench includes: forming a first conductive material lining the trench; forming a second conductive material filling the trench; and performing a planarization process to level the first conductive material with the second conductive material. The method further includes removing the first sacrificial layer and the second sacrificial layer from the stack. The method further includes forming a capacitor dielectric layer over the bottom electrode. The method further includes forming a top electrode over the capacitor dielectric layer.

### BACKGROUND

### Field of Disclosure

The present disclosure relates to a memory device and a method for forming the same.

### Description of Related Art

Memory cells in the dynamic random access memory (DRAM) have been scaled down continuously to integrate a larger number of the memory cells in a unit area. However, this scaling down process can lead to certain problems in the formation of memory cells. For example, as critical dimensions shrink, it becomes more challenging to prevent inclination and collapse of bottom electrodes of trench capacitors having high aspect ratios during fabrication.

Accordingly, how to provide a memory device and a method for forming the same to solve the aforementioned problems becomes an important issue to be solved by those in the industry.

### SUMMARY

An aspect of the disclosure is to provide a memory device and a method for forming the same that may efficiently solve the aforementioned problems.

According to an embodiment of the disclosure, a method for forming a memory device includes forming a stack over a substrate. The stack includes a first supporting layer, a first sacrificial layer, a second supporting layer, a second sacrificial layer, and a third supporting layer. The method further includes forming a trench in the stack. The method further includes forming a bottom electrode in the trench. Forming the bottom electrode in the trench includes: forming a first conductive material lining the trench; forming a second conductive material filling the trench; and performing a planarization process to level the first conductive material with the second conductive material. The method further includes removing the first sacrificial layer and the second sacrificial layer from the stack. The method further includes forming a capacitor dielectric layer over the bottom electrode. The method further includes forming a top electrode over the capacitor dielectric layer.

In an embodiment of the disclosure, the first conductive material is made of titanium nitride or titanium silicon nitride. The second conductive material is made of silicon.

In an embodiment of the disclosure, the first sacrificial layer and the second sacrificial layer are removed from the stack after the second conductive material of the bottom electrode is formed.

In an embodiment of the disclosure, a grain size of the second conductive material is smaller than a grain size of the first conductive material.

In an embodiment of the disclosure, the planarization process is performed to remove portions of the first conductive material and the second conductive material over the third supporting layer.

In an embodiment of the disclosure, the second conductive material is formed spaced apart from the stack through the first conductive material.

In an embodiment of the disclosure, the planarization process is performed to level the first conductive material and the second conductive material with the third supporting layer.

In an embodiment of the disclosure, the first conductive material and the second conductive material are formed in a same chamber.

In an embodiment of the disclosure, the capacitor dielectric layer is in contact with the first conductive material and the second conductive material.

According to another embodiment of the disclosure, a memory device includes a substrate, a capacitor structure, and a supporting layer. The capacitor structure is over the substrate. The capacitor structure includes a bottom electrode, a capacitor dielectric layer, and a top electrode. The bottom electrode includes a first conductive layer and a second conductive layer over the first conductive layer. The capacitor dielectric layer is over the bottom electrode and in contact with both the first conductive layer and the second conductive layer. The top electrode is over the capacitor dielectric layer. The supporting layer is over the substrate and in contact with an outer surface of the bottom electrode of the capacitor structure.

In an embodiment of the disclosure, a top surface of the second conductive layer is level with a top surface of the first conductive layer.

In an embodiment of the disclosure, the first conductive layer includes a different material than the second conductive layer.

In an embodiment of the disclosure, a grain size of the second conductive layer is smaller than a grain size of the first conductive layer.

In an embodiment of the disclosure, the first conductive layer is made of a titanium-based material. The second conductive layer is made of a silicon-containing material.

In an embodiment of the disclosure, the second conductive layer is spaced apart from the supporting layer and the substrate through the first conductive layer.

In an embodiment of the disclosure, a top surface of the second conductive layer is level with a top surface of the supporting layer.

In an embodiment of the disclosure, the capacitor dielectric layer has a substantially flat bottom surface spanning over the supporting layer and the bottom electrode.

In an embodiment of the disclosure, the top electrode and the first conductive layer of the bottom electrode include a first material. The second conductive layer of the bottom electrode includes a second material that is different from the first material.

In an embodiment of the disclosure, the first conductive layer of the bottom electrode cups an underside of the second conductive layer of the bottom electrode.

In an embodiment of the disclosure, the bottom electrode is a solid cylindrical structure.

Accordingly, in the memory device and the method for forming the memory device of some embodiments of the present disclosure, the bottom electrode of the capacitor structure includes two conductive materials and is formed to be a solid cylindrical structure to maintain robustness during fabrication. To be more specific, the bottom electrode includes a first conductive layer and a second conductive layer over the first conductive layer, in which the first conductive layer cups an underside of the second conductive layer. Besides, the second conductive layer has a smaller grain size than the first conductive layer so that the bottom electrode has a dense core, minimizing the risk of deformation or collapse.

It is to be understood that both the foregoing general description and the following detailed description are by examples and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a circuit diagram of a memory cell of a memory device according to an embodiment of the disclosure;

FIG. 2A is a top view of an intermediate stage of a method for forming a memory device according to an embodiment of the disclosure;

FIG. 2B is a partial cross-sectional view of an intermediate stage of a method for forming a memory device along a line B-B of FIG. 2A according to an embodiment of the disclosure;

FIG. 3A is a top view of an intermediate stage of a method for forming a memory device according to an embodiment of the disclosure;

FIG. 3B is a partial cross-sectional view of an intermediate stage of a method for forming a memory device along a line B-B of FIG. 3A according to an embodiment of the disclosure;

FIG. 4 and FIG. 5 are partial cross-sectional views of intermediate stages of a method for forming a memory device according to an embodiment of the disclosure;

FIG. 6A is a top view of an intermediate stage of a method for forming a memory device according to an embodiment of the disclosure;

FIG. 6B is a partial cross-sectional view of an intermediate stage of a method for forming a memory device along a line B-B of FIG. 6A according to an embodiment of the disclosure;

FIG. 7A is a top view of an intermediate stage of a method for forming a memory device according to an embodiment of the disclosure;

FIG. 7B is a partial cross-sectional view of an intermediate stage of a method for forming a memory device along a line B-B of FIG. 7A according to an embodiment of the disclosure; and

FIGS. 8, 9 and 10 are partial cross-sectional views of intermediate stages of a method for forming a memory device according to an embodiment of the disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

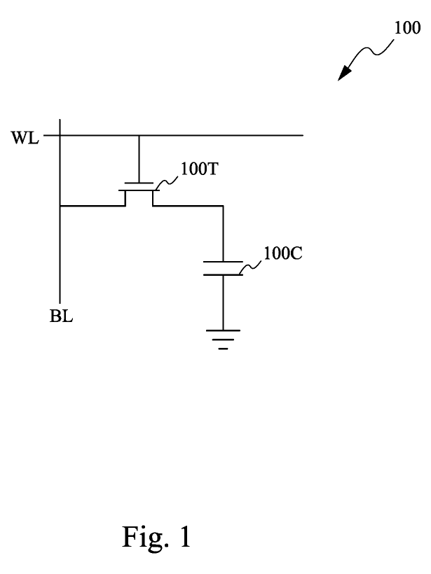

FIG. 1 shows a circuit diagram of a memory cell of a memory device 100 according to an embodiment of the disclosure. In some embodiments, the memory device 100 is a dynamic random access memory (DRAM) device. The memory device 100 includes a transistor 100T, a capacitor 100C, a word line WL, and a bit line BL. The transistor 100T is electrically connected to the word line WL and is also electrically connected to the bit line BL that is arranged perpendicular to the word line WL. One side of the capacitor 100C is electrically connected to the transistor 100T, and the other side of the capacitor 100C is grounded. The operation of devices can be achieved by utilization of the word line WL and the bit line BL, and the storage of data can be accomplished by controlling the charges in the capacitor 100C. The charge transportation over the capacitor 100C can be determined by the control of transistor 100T, which may be manipulated through the bit line BL and the word line WL to characterize the reading and writing of the signal.

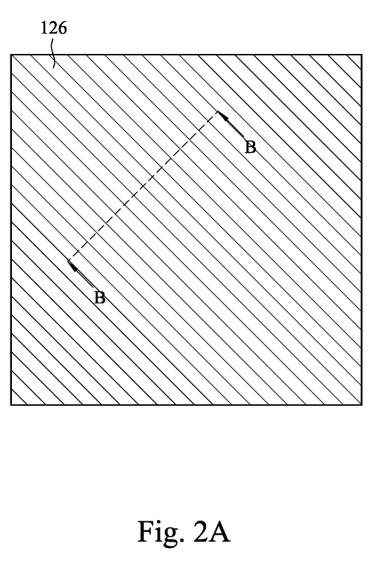

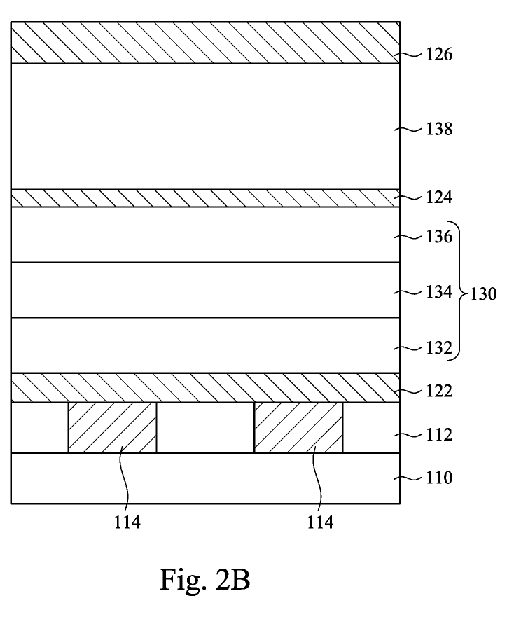

FIGS. 2A to 10 illustrate a method in various intermediate stages of forming the memory device 100 shown in FIG. 1 according to an embodiment of the disclosure. Although FIGS. 2A to 10 are described as a series of acts, it will be appreciated that these acts are not limiting in that the order of the acts can be altered in other embodiments, and the methods disclosed are also applicable to other structures. In some other embodiments, some acts that are illustrated and/or described may be omitted in whole or in part.

Reference is made to FIGS. 2A and 2B in which FIG. 2A is a top view of an intermediate stage of the method for forming the memory device 100, and FIG. 2B is a partial cross-sectional view taken along the line B-B of FIG. 2A.

Shown there is a substrate 110. In some embodiments, the substrate 110 can be suitable semiconductor material, such as silicon (Si), silicon carbide (SiC), gallium arsenide (GaAs), gallium phosphide (GaP), germanium (Ge), indium antimonide (InSb), indium phosphide (InP), indium arsenide (InAs), or the like. The substrate 110 may also be doped with suitable dopants. In some embodiments, a gate structure (not shown in FIGS. 2A and 2B) may be formed in the substrate 110. The gate structure may include a gate dielectric, a gate electrode, and a gate cap. The substrate 110 may include doped regions on opposite sides of the gate structure. The gate structure, the doped regions, and portions of the substrate 110 along a surface of the gate structure (e.g., a channel region) may collectively form the transistor 100T of the memory device 100 as discussed in FIG. 1. In some embodiments, the doped regions may act as source/drain regions of the transistor 100T.

A dielectric layer 112 may be formed over or within the substrate 110. In some embodiments, the dielectric layer 112 may include silicon oxide (SiO), silicon nitride (SiN), silicon oxynitride (SiON), combinations thereof, or the like. In some embodiments, the dielectric layer 112 may be disposed by, for example, atomic layer deposition (ALD), chemical vapor deposition (CVD), physical vapor deposition (PVD), or other suitable methods. The dielectric layer 112 may also be referred to as an interlayer dielectric (ILD).

Contact plugs 114 may be formed in the dielectric layer 112. In some embodiments, the contact plugs 114 may be formed electrically connected to the aforementioned doped regions of the substrate 110. In some embodiments, the contact plugs 114 may include doped polysilicon (poly-Si), titanium (Ti), titanium nitride (TiN), tantalum (Ta), tantalum nitride (TaN), tungsten (W), copper (Cu), aluminum (Al), or an alloy thereof. In some embodiments, the contact plugs 114 may be disposed by, for example, ALD, CVD, PVD, or other suitable methods.

A stack including a supporting layer 122, a sacrificial layer 130, a supporting layer 124, a sacrificial layer 138, and a supporting layer 126 is formed over the substrate 110. The supporting layer 122 is formed over the dielectric layer 112 and the contact plugs 114. The sacrificial layer 130 is formed over the supporting layer 122. The supporting layer 124 is formed over the sacrificial layer 130. The sacrificial layer 138 is formed over the supporting layer 124. The supporting layer 126 is formed over the sacrificial layer 138.

The materials of the supporting layers may be different from the materials of the sacrificial layers. In detail, the supporting layer 122, the supporting layer 124, and the supporting layer 126 may be made of a material exhibiting an etching property different from the sacrificial layer 130 and the sacrificial layer 138. Meanwhile, the material of the sacrificial layer 130 may be different from the material of the sacrificial layer 138. For example, the supporting layer 122, the supporting layer 124, and the supporting layer 126 include silicon nitride. The sacrificial layer 130 includes borophosphosilicate glass (BPSG). The sacrificial layer 138 includes oxide, such as silicon oxide. In some embodiments, the supporting layer 122, the sacrificial layer 130, the supporting layer 124, the sacrificial layer 138, and the supporting layer 126 may be deposited by, for example, ALD, CVD, PVD, or other suitable methods.

In embodiments where the sacrificial layer 130 includes borophosphosilicate glass, dopants, such as boron (B), phosphorus (P), or combinations thereof, are doped. The dopants may weaken the bonding of the silicate of the sacrificial layer 130. Therefore, by adjusting the doping concentration, the sacrificial layer 130 may have a more desired etching property during the subsequent etching process. In greater detail, the sacrificial layer 130 may include sub-layers vertically stacked between the supporting layer 122 and the supporting layer 124. For example, as shown in FIG. 2B, a sub-layer 132, a sub-layer 134, and a sub-layer 136 are sequentially stacked over the supporting layer 122. A dopant concentration of the sub-layer 132 is higher than a dopant concentration of the sub-layer 134. As a result, the bonding of the silicon oxide of the sub-layer 132 is more weakened than that of the sub-layer 134, and the sub-layer 132 is more easily etched than the sub-layer 134. Similarly, the dopant concentration of the sub-layer 134 is higher than a dopant concentration of the sub-layer 136. Thus, the bonding of the silicon oxide of the sub-layer 134 is more weakened than that of the sub-layer 136, and the sub-layer 134 is more easily etched than the sub-layer 136.

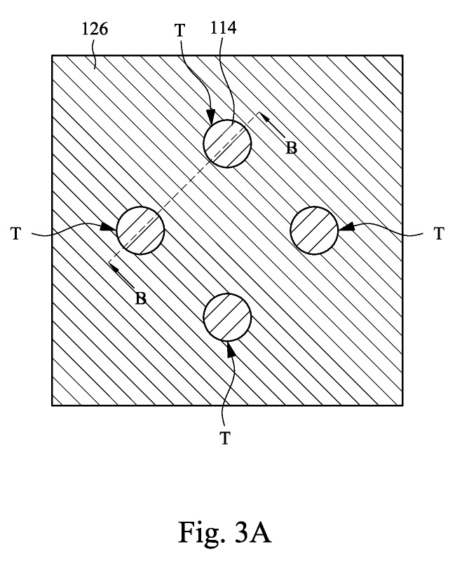

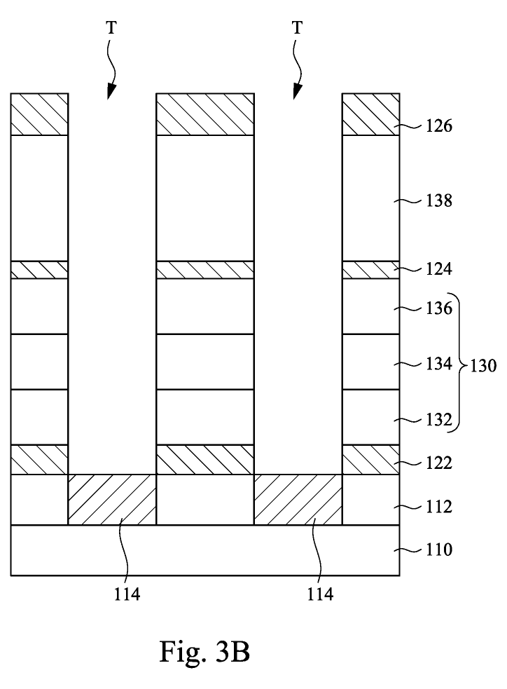

Reference is then made to FIGS. 3A and 3B, in which FIG. 3A is a top view of an intermediate stage of the method for forming the memory device 100, and FIG. 3B is a partial cross-sectional view taken along the line B-B of FIG. 3A.

Trenches T are formed in the stack of the supporting layer 122, the sacrificial layer 130, the supporting layer 124, the sacrificial layer 138, and the supporting layer 126 using suitable photolithography processes. In some embodiments, the trenches T may be formed using an anisotropic dry etching process. After the trenches T are formed, the top surfaces of the contact plugs 114 are exposed.

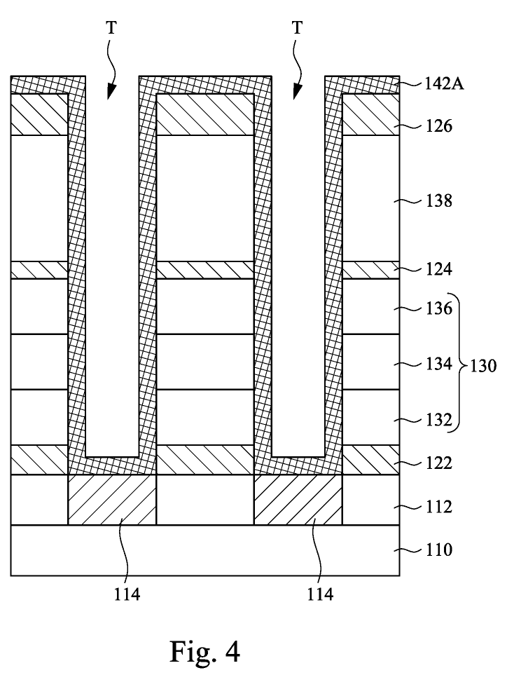

Reference is made to FIG. 4, which illustrates a partial cross-sectional view of an intermediate stage of the method for forming the memory device 100.

After the formation of the trenches T, a first conductive material 142A is formed lining the trenches T and a top surface of the supporting layer 126. In addition, the formed first conductive material 142A is in contact with the top surfaces of the contact plugs 114.

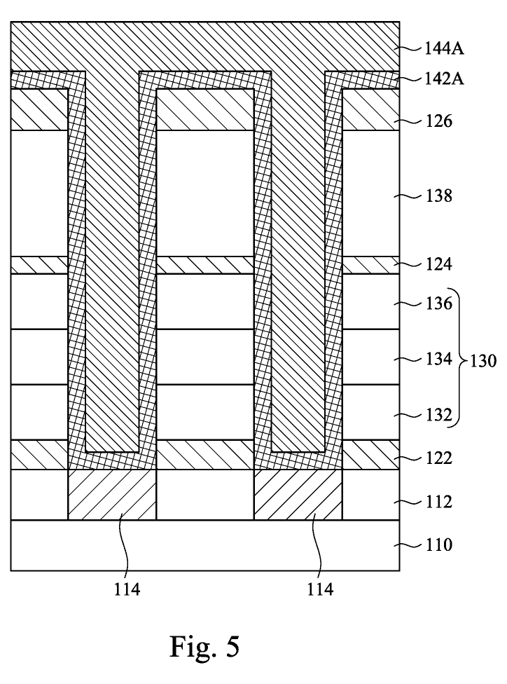

Reference is made to FIG. 5, which illustrates a partial cross-sectional view of an intermediate stage of the method for forming the memory device 100.

Then, a second conductive material 144A is formed filling the trenches T and covering the first conductive material 142A. The second conductive material 144A is spaced apart from the stack and the substrate 110 through the first conductive material 142A. In some embodiments, the second conductive material 144A overfills the trenches T and extends over the top surface of the supporting layer 126.

In some embodiments, the first conductive material 142A includes a different material than the second conductive material 144A. For example, the first conductive material 142A is made of titanium-based material, such as titanium silicon nitride (TiSiN) or titanium nitride, and the second conductive material 144A is made of silicon-containing material, such as silicon, or more particularly, polysilicon.

In some embodiments, a grain size of the second conductive material 144A is smaller than a grain size of the first conductive material 142A. As a result, the second conductive material 144A presents better gap-filling capability than the first conductive material 142A. To be more specific, in embodiments where the first conductive material 142A contains TiSiN and the second conductive material 144A contains polysilicon, forming the second conductive material 144A over the first conductive material 142A and overfilling the trenches T can produce denser fillers than overfilling the trenches T using only the first conductive material 142A. In addition, polysilicon thin films exhibit less residual stress than TiSiN thin films, minimizing the risk of deformation.

In some embodiments, the first conductive material 142A and the second conductive material 144A are formed in a same chamber. For example, the first conductive material 142A containing TiSiN is firstly deposited by CVD using titanium tetrachloride (TiCl₄), silane (SiH₄), and ammonia (NH₃) as precursors in a CVD reactor. Then, the second conductive material 144A containing poly-Si is deposited using SiH₄ as a precursor in the same CVD reactor. As a result, the trenches T can be entirely filled before the intermediate structure is transferred to another chamber for subsequent processes, thereby enhancing rigidity of the intermediate structure.

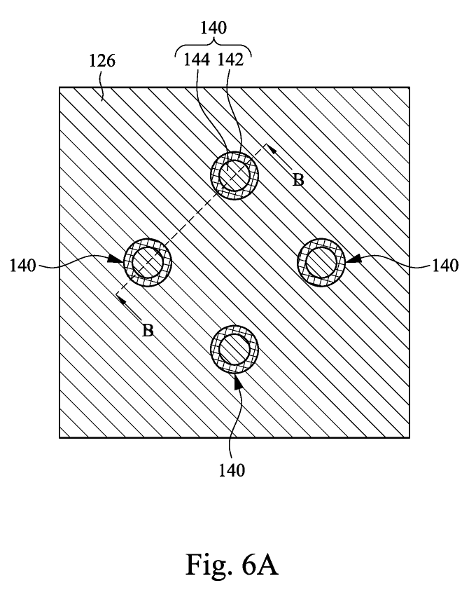

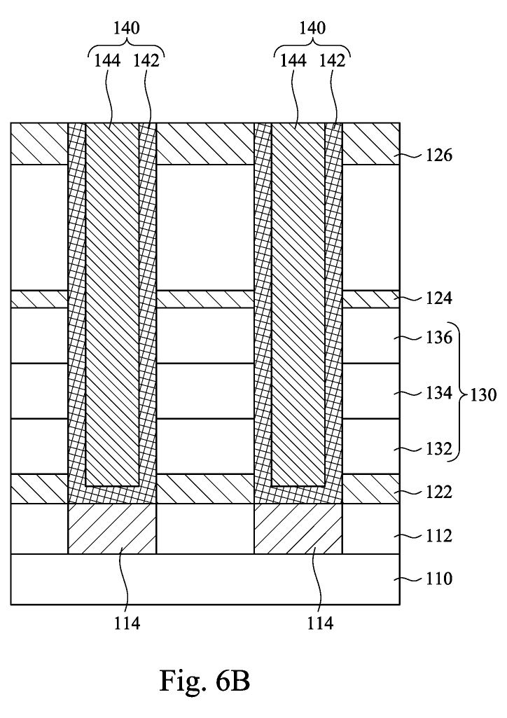

Reference is then made to FIGS. 6A and 6B, in which FIG. 6A is a top view of an intermediate stage of the method for forming the memory device 100, and FIG. 6B is a partial cross-sectional view taken along the line B-B of FIG. 6A.

A planarization process such as chemical mechanical planarization (CMP) is performed to level the first conductive material 142A with the second conductive material 144A. In greater detail, portions of the first conductive material 142A and the second conductive material 144A over the supporting layer 126 are removed to expose the top surface of the supporting layer 126 and level the first conductive material 142A and the second conductive material 144A with the supporting layer 126. The remaining portions of the first conductive material 142A are referred to as first conductive layers 142. The remaining portions of the second conductive material 144A are referred to as second conductive layers 144. Accordingly, bottom electrodes 140 including the first conductive layers 142 and the second conductive layers 144 are formed respectively into the trenches T. In the cross-sectional view of FIG. 6B, the first conductive layer 142 has a U-shape cross-section, while the second conductive layer 144 has a rectangular cross-section. The first conductive layer 142 and the second conductive layer 144 form a solid cylindrical structure. To be more specific, the first conductive layer 142 and the second conductive layer 144 form a solid cylindrical pillar without an internal cavity. The formed bottom electrodes 140 are in contact with the respective contact plugs 114. Thus, the bottom electrodes 140 may be electrically connected with the doped regions in the substrate 110.

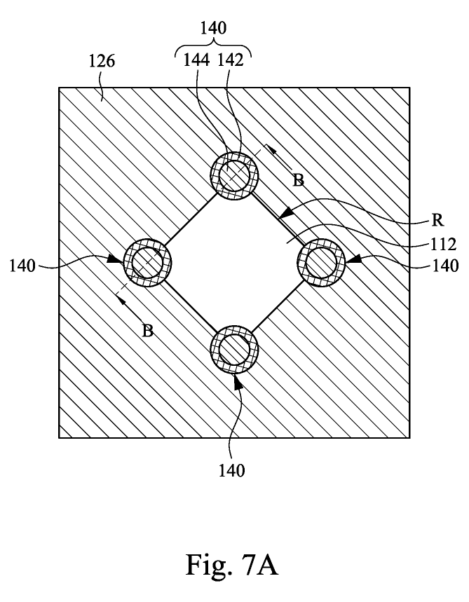

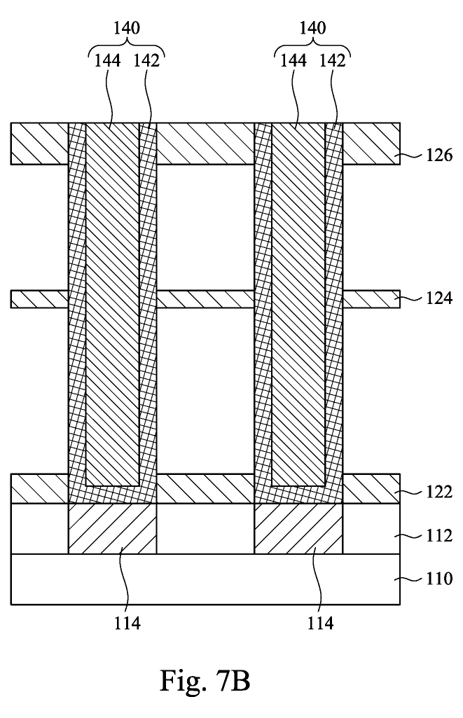

Reference is made to FIGS. 7A and 7B, in which FIG. 7A is a top view of an intermediate stage of the method for forming the memory device 100, and FIG. 7B is a partial cross-sectional view taken along the line B-B of FIG. 7A.

After the bottom electrodes 140 are formed, an etching process is performed to remove portions of the supporting layer 122, the sacrificial layer 130, the supporting layer 124, the sacrificial layer 138, and the supporting layer 126 to form a recess R. For example, as shown in FIG. 7A, the recess R is enclosed by the four bottom electrodes 140 and exposes the dielectric layer 112 over the substrate 110. In some embodiments, the etching process may be performed through a patterned mask that is formed over the supporting layer 126 and has an opening defining the position of the recess R.

Then, another etching process such as wet etching is performed through the recess R to remove the sacrificial layer 130 and the sacrificial layer 138 from the stack. As a result, the supporting layer 124 and the supporting layer 126 suspend over the substrate 110, as shown in FIG. 7B. In greater detail, top surfaces of the supporting layer 122, the supporting layer 124, and the supporting layer 126 are exposed, and bottom surfaces of the supporting layer 124 and the supporting layer 126 are exposed. In addition, the outer surfaces of the U-shaped first conductive layers 142 are partially exposed. As aforementioned, the bottom electrodes 140 are solid cylindrical structures. Thus, the bottom electrodes 140 can remain structurally robust after the sacrificial layers are removed.

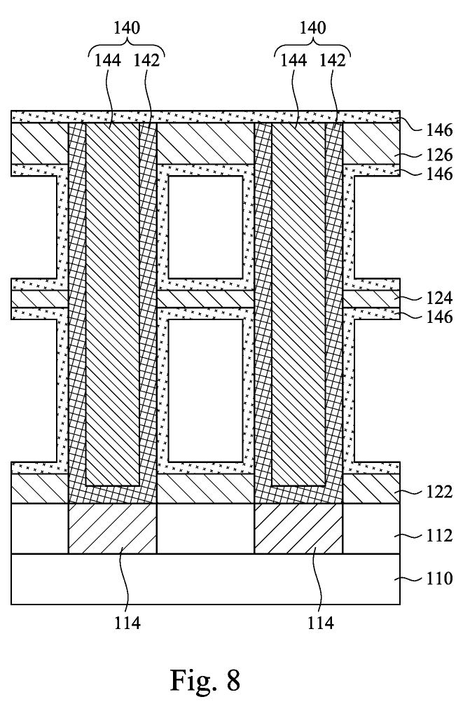

Reference is then made to FIG. 8 to FIG. 10, which illustrate partial cross-sectional views of intermediate stages of the method for forming the memory device 100.

As shown in FIG. 8, a capacitor dielectric layer 146 is formed over the bottom electrode 140. In some embodiments, the capacitor dielectric layer 146 is in contact with a top surface of the bottom electrode 140. More particularly, the capacitor dielectric layer 146 is in contact with both the first conductive layer 142 and the second conductive layer 144. In addition, the capacitor dielectric layer 146 is formed over the exposed surfaces of the supporting layer 122, the supporting layer 124, the supporting layer 126, and the first conductive layer 142. To be more specific, as shown in FIG. 8, the capacitor dielectric layer 146 is formed over the top surfaces of the supporting layer 122, the supporting layer 124, and the supporting layer 126. The capacitor dielectric layer 146 is also formed over the bottom surfaces of the supporting layer 124 and the supporting layer 126. The capacitor dielectric layer 146 is also formed over the outer surfaces of the first conductive layer 142. In some embodiments, the capacitor dielectric layer 146 may be made of zirconium oxide (ZrO), hafnium oxide (HfO), aluminum oxide (Al₂O₃), silicon oxide, or the like.

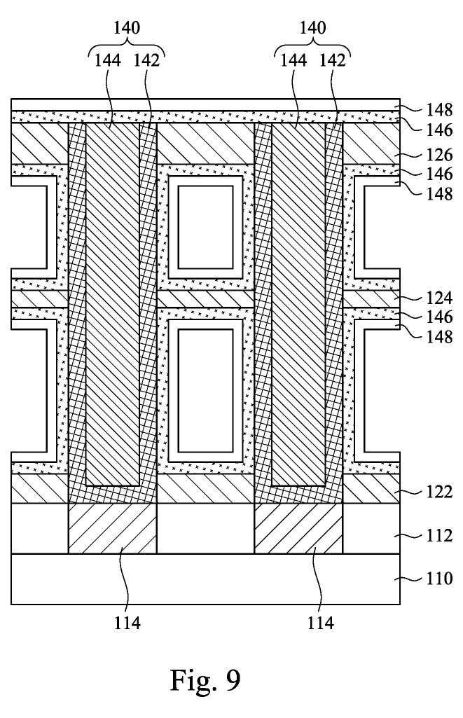

As shown in FIG. 9, a top electrode 148 is formed over the capacitor dielectric layer 146. In some embodiments, the top electrode 148 may be made of a same material as the first conductive layer 142 of the bottom electrode 140. For example, the top electrode 148 may include TiSiN or TiN. Accordingly, the bottom electrode 140, the capacitor dielectric layer 146, and the top electrode 148 collectively serve as a capacitor structure.

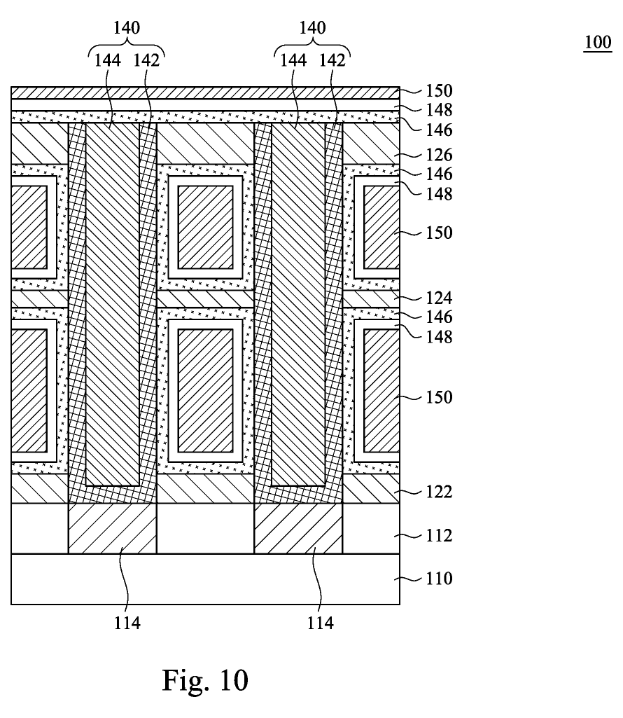

As shown in FIG. 10, an insulating layer 150 is formed over the top electrode 148 and filling the remaining spaces in the structure shown in FIG. 9. In some embodiments, the insulating layer 150 may include, for example, borophosphosilicate glass (BPSG), tetraethyl orthosilicate (TEOS), phosphorus doped tetraethyl orthosilicate (PTEOS), molding compound, or other suitable materials.

As shown in FIG. 10, the resultant memory device 100 includes a substrate 110, capacitor structures over the substrate 110, and supporting layers over the substrate 110 and in contact with the capacitor structures.

The substrate 110 may be any suitable semiconductor material and may be doped with suitable dopants. As aforementioned, gate structures (not shown in FIG. 10) may be disposed in the substrate 110. A dielectric layer 112 may be disposed over or within the substrate 110. Contact plugs 114 may be disposed in the dielectric layer 112 and electrically connected to doped regions of the substrate 110.

The capacitor structures are over the substrate 110 and include a bottom electrode 140, a capacitor dielectric layer 146, and a top electrode 148, respectively.

The bottom electrode 140 is disposed over the respective contact plug 114 and in contact with its top surface to be electrically connected to the doped regions of the substrate 110. The bottom electrode 140 includes a first conductive layer 142 and a second conductive layer 144 over the first conductive layer 142. The first conductive layer 142 cups an underside of the second conductive layer 144. To be more specific, the first conductive layer 142 has a U-shape cross-section, while the second conductive layer 144 has a rectangular cross-section. The first conductive layer 142 and the second conductive layer 144 form a solid cylindrical structure without an internal cavity. In addition, the second conductive layer 144 is spaced apart from the supporting layers and the substrate 110 through the first conductive layer 142. Moreover, a top surface of the second conductive layer 144 is level with a top surface of the first conductive layer 142. In some embodiments, the top surfaces of the first conductive layer 142 and the second conductive layer 144 are level with a top surface of the supporting layer 126.

In some embodiments, the first conductive layer 142 of the bottom electrode 140 includes a different material than the second conductive layer 144 of the bottom electrode 140. For example, the first conductive layer 142 is made of titanium-based material, such as TiSiN or TiN, and the second conductive layer 144 is made of silicon-containing material, such as silicon, or more particularly, polysilicon. In such embodiments, since polysilicon has a smaller grain size than TiSiN and TiN, polysilicon presents better gap-filling capability and help form a dense, solid pillar structure as the bottom electrode 140, providing a reinforced structure that is more resistant to collapse.

The supporting layers include a supporting layer 122, a supporting layer 124, and a supporting layer 126. The supporting layer 122 is over the dielectric layer 112. The supporting layer 124 is over the supporting layer 122. The supporting layer 126 is over the supporting layer 124. The supporting layer 122, the supporting layer 124, and the supporting layer 126 are in contact with different parts of the outer surface of the first conductive layer 142 of the bottom electrode 140. In some embodiments, the supporting layer 122, the supporting layer 124, and the supporting layer 126 include silicon nitride.

The capacitor dielectric layer 146 is over the bottom electrode 140 and in contact with both the first conductive layer 142 and the second conductive layer 144. Since the top surfaces of the first conductive layer 142, the second conductive layer 144, and the supporting layer 126 are level, the capacitor dielectric layer 146 has a substantially flat bottom surface spanning over the supporting layer 126 and the bottom electrode 140. In addition, the capacitor dielectric layer 146 is over the top surfaces of the supporting layer 122, the supporting layer 124, and the supporting layer 126. The capacitor dielectric layer 146 is also over the bottom surfaces of the supporting layer 124 and the supporting layer 126. The capacitor dielectric layer 146 is also along the outer surface of the first conductive layer 142.

The top electrode 148 is over the capacitor dielectric layer 146. In some embodiments, the top electrode 148 may include a same material as the first conductive layer 142 of the bottom electrode 140. For example, the top electrode 148 may include TiSiN or TiN. In other words, the top electrode 148 may include a different material than the second conductive layer 144 of the bottom electrode 140.

In some embodiments, the memory device 100 may further include an insulating layer 150 over the top electrode 148. Also, the insulating layer may be between adjacent bottom electrodes 140.

Accordingly, in the memory device and the method for forming the memory device of some embodiments of the present disclosure, the bottom electrode of the capacitor structure includes two conductive materials and is formed to be a solid cylindrical structure to maintain robustness during fabrication. To be more specific, the bottom electrode includes a first conductive layer and a second conductive layer over the first conductive layer, in which the first conductive layer cups an underside of the second conductive layer. Besides, the second conductive layer has a smaller grain size than the first conductive layer so that the bottom electrode has a dense core, minimizing the risk of deformation or collapse.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. A method for forming a memory device, comprising:
forming a stack over a substrate, wherein the stack comprises a first supporting layer, a first sacrificial layer, a second supporting layer, a second sacrificial layer, and a third supporting layer;
forming a trench in the stack;
forming a bottom electrode in the trench, comprising:
forming a first conductive material lining the trench;
forming a second conductive material filling the trench; and
performing a planarization process to level the first conductive material with the second conductive material;
removing the first sacrificial layer and the second sacrificial layer from the stack;
forming a capacitor dielectric layer over the bottom electrode; and
forming a top electrode over the capacitor dielectric layer.

2. The method of claim 1, wherein the first conductive material is made of titanium nitride or titanium silicon nitride, and the second conductive material is made of silicon.

3. The method of claim 1, wherein the first sacrificial layer and the second sacrificial layer are removed from the stack after the second conductive material of the bottom electrode is formed.

4. The method of claim 1, wherein a grain size of the second conductive material is smaller than a grain size of the first conductive material.

5. The method of claim 1, wherein the planarization process is performed to remove portions of the first conductive material and the second conductive material over the third supporting layer.

6. The method of claim 1, wherein the second conductive material is formed spaced apart from the stack through the first conductive material.

7. The method of claim 1, wherein the planarization process is performed to level the first conductive material and the second conductive material with the third supporting layer.

8. The method of claim 1, wherein the first conductive material and the second conductive material are formed in a same chamber.

9. The method of claim 1, wherein the capacitor dielectric layer is in contact with the first conductive material and the second conductive material.

10. A memory device, comprising:
a substrate;
a capacitor structure over the substrate and comprising:
a bottom electrode comprising a first conductive layer and a second conductive layer over the first conductive layer;
a capacitor dielectric layer over the bottom electrode and in contact with both the first conductive layer and the second conductive layer; and
a top electrode over the capacitor dielectric layer; and
a supporting layer over the substrate and in contact with an outer surface of the bottom electrode of the capacitor structure.

11. The memory device of claim 10, wherein a top surface of the second conductive layer is level with a top surface of the first conductive layer.

12. The memory device of claim 10, wherein the first conductive layer comprises a different material than the second conductive layer.

13. The memory device of claim 10, wherein a grain size of the second conductive layer is smaller than a grain size of the first conductive layer.

14. The memory device of claim 10, wherein the first conductive layer is made of a titanium-based material and the second conductive layer is made of a silicon-containing material.

15. The memory device of claim 10, wherein the second conductive layer is spaced apart from the supporting layer and the substrate through the first conductive layer.

16. The memory device of claim 10, wherein a top surface of the second conductive layer is level with a top surface of the supporting layer.

17. The memory device of claim 10, wherein the capacitor dielectric layer has a substantially flat bottom surface spanning over the supporting layer and the bottom electrode.

18. The memory device of claim 10, wherein the top electrode and the first conductive layer of the bottom electrode comprise a first material, and the second conductive layer of the bottom electrode comprises a second material that is different from the first material.

19. The memory device of claim 10, wherein the first conductive layer of the bottom electrode cups an underside of the second conductive layer of the bottom electrode.

20. The memory device of claim 10, wherein the bottom electrode is a solid cylindrical structure.
